(19) United States
(12) Patent Application Publication
(10) Pub. No.: US 2013/0014814 A1
(43) Pub. Date: Jan. 17, 2013

(54) NANOSTRUCTURED ARRAYS FOR RADIATION CAPTURE STRUCTURES

(71) Applicants: Sang Eon Han, Cambridge, MA (US); Anastassios Mavrokefalos, Cambridge, MA (US); Matthew Sanders Branham, Cambridge, MA (US); Gang Chen, Carlisle, MA (US)

(72) Inventors: Sang Eon Han, Cambridge, MA (US); Anastassios Mavrokefalos, Cambridge, MA (US); Matthew Sanders Branham, Cambridge, MA (US); Gang Chen, Carlisle, MA (US)

(73) Assignee: Massachusetts Institute of Technology, Cambridge, MA (US)

(21) Appl. No.: 13/513,928

(22) PCT Filed: Jan. 10, 2011
(86) PCT No.: PCT/US2011/020651

§ 371 Date: Sep. 11, 2012

Related U.S. Application Data
(60) Provisional application No. 61/293,454, filed on Jan. 8, 2010.
(60) Provisional application No. 61/361,678, filed on Jul. 6, 2010.

(51) Int. Cl. H01L 31/0248

(52) U.S. Cl. 136/255

(57) ABSTRACT

Silicon nanohole arrays are disclosed as light absorbing structures for various devices such as solar photovoltaics. To obtain the same ultimate efficiency as a standard 300 micrometer crystalline silicon wafer, nanohole arrays require less silicon by mass. Moreover, calculations suggest that nanohole arrays may have efficiencies superior to nanorod arrays for practical thicknesses. With well-established fabrication techniques, nanohole arrays have great potential for efficient solar photovoltaics.

### FEDERALLY SPONSORED RESEARCH

This invention was made with government support awarded by the National Science Foundation under Grant Number 00006178. The U.S. Government has certain rights in this invention.

### TECHNICAL FIELD

The invention concerns photon processing structures and, in particular, light absorbing structures, which can be used in photovoltaics.

### BACKGROUND OF THE INVENTION

Poor infrared absorption of crystalline silicon (c-Si) resulting from its indirect band gap poses a challenge to its use in solar photovoltaics. Currently, commercial solar cells have 200-300 micrometer c-Si active layers that absorb light efficiently. This thickness accounts for ˜40% of the total module cost and needs to be reduced to several micrometers. A thinner active layer has the added advantage of efficient charge-carrier transport. Thus, an effective technique for light trapping in thin active layers needs to be developed.

While various structures employing randomly or periodically structured surfaces, nanoparticles or other plasmonic structures to increase absorption in thin film photovoltaics have been investigated, an alternative strategy is to structure the active layer itself. For example, vertically aligned nanorod or nanocone arrays of active layers have been considered. Theoretical studies have shown that these structures can improve light absorption and carrier collection, leading to higher efficiency. For nanorod arrays, one can construct a p-n or a p-i-n junction in the radial direction of each nanorod to shorten the carrier diffusion length. However, fabrication of these structures can sometimes be difficult.

There remains a need for improved photovoltaic devices with high light absorption properties.

### SUMMARY OF THE INVENTION

Silicon nanohole arrays are disclosed as light absorbing structures for various devices such as solar photovoltaics. To obtain the same ultimate efficiency as a standard 300 micrometer crystalline silicon wafer, nanohole arrays require less silicon by mass. Moreover, calculations suggest that nanohole arrays may have efficiencies superior to nanorod arrays for practical thicknesses. With well-established fabrication techniques, nanohole arrays have great potential for efficient solar photovoltaics.

While past theoretical and experimental studies have mostly focused on nanorod arrays, alternative structures for photovoltaics can be based on nanohole arrays which can be produced using different fabrication techniques. In a well-established technique, highly ordered holes are produced on a c-Si wafer by lithography and subsequent etching in acid. Additional fabrication techniques can be adapted from the methods described by Birner, A.; Wehrspohn, R. B.; Gosele, U. M.; Busch, K. Adv. Mater. 2001, 13, 377; Klühr, M. H.; Sauermann, A.; Elsner, C. A.; Thein, K. H.; Dertinger, S. K. Adv. Mater. 2006, 18, 3135; Richter, S.; Hillebrand, R.; Jamois, C.; Zacharias, M.; Gosele, U.; Schweizer, S. L.; Wehrspohn, R. B. Phys. Rev. B 2004, 70, 193302 or Wehrspohn, R. B.; Schweizer, S. L.; Sandoghdar, V. Phys. Stat. Sol. (a) 2007, 204, 3708, the teachings of which are incorporated herein by reference.

Dielectric nanohole arrays have been studied primarily in the context of photonic crystals. Light propagation perpendicular to the hole axis has been the chief focus of these studies. In the present disclosure, the light trapping characteristics of nanohole arrays for photovoltaics are reported and compared to those of nanorod arrays. It has been discovered that nanohole arrays are comparable to, or even better than, nanorod arrays in terms of light absorption.

In certain embodiments, the photovoltaic structures can comprise a semiconductor lattice structure exhibiting a plurality of nanoholes and a semiconductor lining disposed at least partially within the nanoholes. While the photovoltaic structures can take many shapes and forms, in some embodiments, particularly advantageous lattice structures can be formed from nanostructures having the shape of pyramids. The lattice structure can be formed from a first dopant type (e.g., a p or n type doped c-Si), and the lining can be formed from a second dopant type to provide a p-n junction to light impinging upon and/or propagating within the structure. In some embodiments the junction can be a radial junction. The junction can be a homojunction or a heterojunction. The nanoholes can be sized to substantially trap incident light and facilitate carrier separation. For example, the depth of the nanoholes can be greater than about 100 nm or, in other applications greater than about 1, 2, or 3 μm, to about 200 μm. In some embodiments, the lattice structure can be characterized by a lattice constant, which can be in a range from about 300 nm to about 700 nm, or about 400 nm to about 650 nm and/or a fill fraction in a range from about 0.25 to about 0.75. While in some embodiments the nanoholes can completely penetrate through a substrate body (e.g., forming a tunnel therethrough), in other embodiments at least one of the plurality of nanoholes penetrates only partially through the semiconductor lattice structure. For example, the partially penetrating nanohole can exhibit a depth less than about 2 μm, 1.5 μm, 1 μm, 900 nm, 800 nm, 700 nm, 600 nm, 500 nm, 450 nm, 400 nm or greater or lesser or intermediate values.

Another aspect of the invention is directed to a radiation absorbing structure, which can include a semiconductor lattice comprising at least a first and a second layer of semiconductor material, the second semiconductor material having a different dopant composition relative to the first semiconductor material. The lattice can be porous and can have a plurality of light trapping holes. The structure of the lattice and nanoholes can include any of the features disclosed herein.

In some aspects, the invention can comprise a plurality of holes in a substrate having any of the fill fractions, lattice constants, and depths described herein. The substrate can be a c-Si substrate, which can be optionally doped (e.g., low n-doping or low p-doping). As discussed throughout the present disclosure, a c-Si substrate can either be a single crystal silicon material, or a polycrystalline silicon material, and can be distinguished from an amorphous silicon substrate. The holes can be formed using any appropriate technique including those known by a skilled artisan. For instance, the holes can be formed using etching techniques. The walls of the holes can be at least partially covered by a material having a different character than the substrate, such as a c-Si material having opposite doping relative to the substrate (e.g., if the substrate is n-doped, the coating can be p-doped). The coating can be deposited using any number of techniques, including those known in the art such as wet chemical methods, chemical vapor deposition (e.g., in providing a p-type layer), diffusion (e.g., having a p-type substrate with etched holes and diffusing a n-type material through the walls of the holes), and epitaxial methods. Alternatively, layers of semiconductor materials (e.g., one n-type layer and one p-type layer) can be provided adjacent to one another. Pyramids and/or other types of nanoholes can be etched, or otherwise provided, to penetrate into both layers to form the lattice structure. In some embodiments, the lattice can be periodic while in other embodiments the lattice can be random.

Other aspects of the present invention are directed to nanoscale radiation capture structures including a first doped layer and a second doped layer each contacting a p-n junction. The first doped layer can be characterized by a plurality of nanostructures, such as pyramids or holes, on a surface of the first doped layer. The nanostructures, which are optionally periodically disposed on the surface of the first doped layer, can include at least one of a nanoprotrusion and a nanopit (e.g., a structure, such as a hole or an inverted pyramid, that can only partially penetrate into the first doped layer), wherein each nanostructure can extend a selected distance from the surface of first doped layer (e.g., a distance less than about 500 nm or less than about 2 microns), and in some embodiments, can protrude at least partially into the second doped layer. The nanostructures can be configured to enhance at least one of photon capture and charge separation properties of the radiation capture structure when radiation contacts the surface of the first doped layer.

In some embodiments, the radiation capture structure comprises a c-Si material, such as a c-Si layer that can include one or more of the first doped layer and the second doped layer. In another embodiment, the first doped layer can comprise a crystalline substrate with a (100) orientation. In other embodiments, the first doped layer can exhibit a thickness of greater than about 1 micron. In embodiments where the nanostructures are pyramids, the pyramids can include an apex and base oriented such that the apex is closer to a p-n junction of a bilayer than the base (e.g., the pyramids are inverted and are pits in a surface of the substrate), or the base is closer to the p-n junction than the apex (e.g., the pyramids protrude from a surface of the substrate). Furthermore, pyramid structures can exhibit a lattice constant in a range from about 400 nm to about 1200 nm.

In other embodiments, the plurality of nanostructures (e.g., pyramids) can comprise a plurality of skewed nanostructures, which can act to enhance at least one of photon capture and charge separation relative to a plurality of non-skewed nanostructures which are similarly disposed. Such skewed nanostructures can be disposed in a lattice arrangement on the surface of the first doped layer (e.g., a triangle or square), which can help break the mirror symmetry of the nanostructures.

While these nanoscale radiation capture structures can be utilized in a variety of devices, in some embodiments the structures are utilized as part of a photovoltaic device. In such devices, the radiation capture structure can include a reflector layer coupled with the first and second doped layers and can be configured to increase the optical path length of photons captured by the radiation capture structure. A transparent electrode and/or an antireflection coating can also be included and coupled to the surface of the first doped layer. A first electrical contact can be coupled to the first doped layer and/or a second electrical contact can be coupled to the second doped layer.

### FIGURES

FIG. 1A is a schematic illustration of an exemplary nanohole and nanorod array;

FIG. 1B is a graphical plot of the calculated absorptance at λ=670 nm as a function of c-Si filling fraction for the nanohole and the nanorod array structures occupying a half space;

FIG. 1C is a graphical plot of the dispersion relation for the nanohole array structures for different c-Si filling fractions in the direction of the hole axis;

FIG. 2 is a graphical plot of the calculated absorptance spectra for the nanohole and the nanorod array structures when the thickness d is 2.33 μm and 1.193 mm;

FIG. 3 is a graphical plot of the calculated ultimate efficiency as a function of the lattice constant of the nanohole and the nanorod array structures for various filling fractions when the thickness is 2.33 μm;

FIG. 4 is a graphical plot of the calculated ultimate efficiency as a function of the thickness of the nanohole array, the nanorod array, and the homogeneous c-Si film (a) with and (b) without a Si₃N₄ antireflection (AR) coating;

FIG. 5 is a graphical plot of the calculated ultimate efficiency for the nanohole and the nanorod array as a function of the angle from the surface normal for transverse-electric (TE) and transverse-magnetic (TM) polarizations;

FIG. 6 graphical plot of the ultimate efficiency as a function of the depth of nanoholes on a c-Si film of thickness 2.33 μm;

FIG. 7A is a perspective view of an exemplary nanoprotrusion in the form of nanopyramids;

FIG. 7B is a perspective view of an exemplary nanopit in the form of nanoinverted-pyramid;

FIG. 8 is a graphical plot of the ultimate efficiency as a function of the lattice constant of an inverted pyramid array on a c-Si film of thickness 2.33 μm;

FIG. 9 is a graphical plot of the absorption spectra for the nanohole and the inverted pyramid array structures when the c-Si film thickness is 2.33 μm;

FIG. 10A is a schematic illustration of an exemplary photovoltaic device structure in the form of an inverted pyramid nanostructured silicon device;

FIG. 10B is a schematic illustration of an exemplary photovoltaic device structure in the form of a pyramid nanostructured silicon device;

FIG. 10C is a schematic illustration of an exemplary photovoltaic device structure of FIG. 10A with the back contact made through the handling wafer;

FIG. 10D is a schematic illustration of an exemplary photovoltaic device structure of FIG. 10B with the back contact made through the handling wafer;

FIG. 11A is a schematic illustration of an exemplary symmetric electric field in a structure with a mirror symmetry;

FIG. 11B is a schematic illustration of an exemplary antisymmetric electric field in a structure with a mirror symmetry;

FIG. 12 is a perspective view of a triangular array of skewed pyramids;

FIG. 13 is a graphical plot of calculated absorption spectra for the pyramid square array, inverted pyramid square array, the skew pyramid triangular array, and the Lambertian limit when the c-Si film thickness is 2.33 μm; and

FIG. 14 is a graphical plot of calculated ultimate efficiency as a function of the thickness of the homogeneous c-Si film, the nanoholes, the inverted pyramids, and the skewed pyramids with a Si₃N₄ antireflection (AR) coating.

### DETAILED DESCRIPTION

To evaluate the absorption performance of solar cells, we calculate the ultimate efficiency, η, which is defined as the efficiency of a photovoltaic cell as the temperature approaches 0° K when each photon with energy greater than the band gap produces one electron-hole pair:

$$η = \frac{{\int }_{0}^{{λ}_{g}} I ( λ ) A ( λ ) \frac{λ}{{λ}_{g}} d λ}{{\int }_{0}^{∞} I ( λ ) d λ} , \qquad ( 1 )$$

where I is the solar intensity per wavelength interval, A the absorptance, λ the wavelength, and λ_{g} the wavelength corresponding to the band gap. For the solar intensity, we use the Air Mass 1.5 spectrum. Equation (1) shows that, for a given absorption and solar radiation spectrum, λ/λ_{g} can be regarded as a weighting factor for integration. As the wavelength decreases from the band gap, the contribution of the absorbed solar energy to the ultimate efficiency decreases because the excess energy of photons above the band gap is wasted. Thus, while the solar Air Mass 1.5 spectrum peaks around 500 nm, the largest contribution to the ultimate efficiency of a c-Si solar cell comes from wavelengths around 670 nm.

### Nanohole Structures

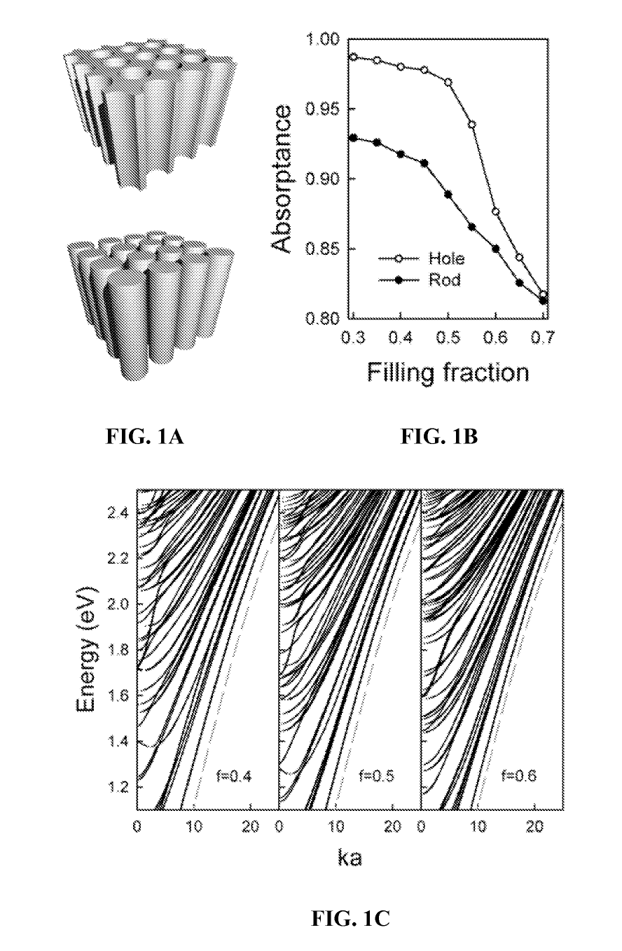

The coupling between 670 nm light and the structures has been investigated. Light is assumed to be incident along the hole/rod axis of the nanoholes and nanorods illustrated in FIG. 1A. As the wavelength is comparable to the lattice constant (e.g., the distance between adjacent structures on a periodic array such as the side of a unit cell of a square or triangular array), one expects strong optical diffraction. If a single eigenmode were excited inside the structures, an impedance model can be used to calculate reflectance for an infinitely thick structure. However, as will be shown later, many modes can be excited. Instead of a single eigenmode impedance model, we directly calculate the normal absorptance for infinite thickness by varying the c-Si filling fraction f. As an example, for calculations, one can use the transfer matrix method described by Bell, P. M.; Pendry, J. B.; Martin-Moreno, L.; Ward, A. J. Comput. Phys. Commun. 1995, 85, 306. with the dielectric functions described by the Handbook of Optical Constants of Solids; Palik, E. D., Ed.; Academic; Orlando, Fla., 1985 and select the lattice constant to be 500 nm. A lattice constant of 500 nm is close to the optimum ultimate efficiency condition found in previous studies for nanorod arrays.

FIG. 1B shows that absorption increases as the filling fraction, f, decreases in both nanohole and nanorod arrays as a result of the smaller optical density, which creates antireflection effect. In the case of nanorods, the filling fraction is defined as the volume of solid per overall volume of the structure. In the case of nanoholes, the filling fraction is defined as the volume of the holes per volume of structure. Over the entire range of the investigated filling fraction, nanohole arrays show better light coupling than nanorod arrays. For nanohole arrays, absorption decreases when the filling fraction exceeds 0.5. Since absorption will not be efficient for thin structures if the filling fraction is too small, some embodiments of a c-Si trapping structure use a filling fraction close to 0.5. In some applications, the fill fraction can from vary from about 25% to about 75% or preferably between 40% to 60%.

The propagation of light inside nanohole arrays can be investigated by using the photonic band structure shown in FIG. 1C. The wavevector k is in the direction of the nanohole axis and normalized by the lattice constant (a=500 nm) in the plane perpendicular to the direction. Three important observations on the band structure: first, many bands are formed above the Si band gap of 1.1 eV. This is because the waveguide cutoff for the fundamental mode is located at low frequencies and many higher modes are excited in the frequency ranges of interest. Second, the bands shift to lower frequencies as the filling fraction increases because the frequencies of waveguide modes decrease as the size of the waveguide (Si) increases. This implies that, at a specific frequency, light propagation becomes more complicated for higher filling fractions because a greater number of modes will be available. Third, the group velocities of the bands are mostly lower than those of the light line for homogeneous Si (gray dashed line in FIG. 1C). The combination of a large number of bands and the relatively small group velocities implies a higher density of states of photons and hence larger absorption above that for a homogeneous film.

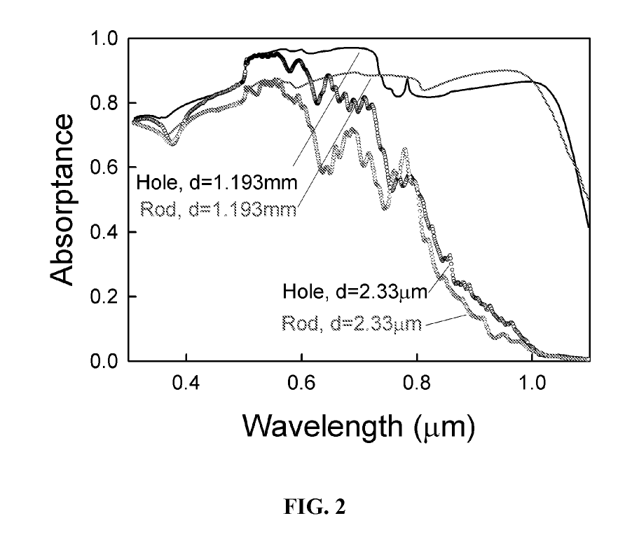

Guided by the calculations summarized by FIGS. 1A-1C, the parameters a=500 nm and f=0.5 can be used to calculate the absorption spectra for the nanohole and the nanorod array. FIG. 2 gives the results when the thickness d of the structures is 1.193 mm and 2.33 micrometers. In both cases, absorption is higher for the nanohole array when λ is less than approximately 750 nm. When d=1.193 mm, the nanohole array gives a slightly higher ultimate efficiency of 42.6% compared to 41.2% for the nanorod array. However, when d=2.33 μm, the efficiency is 27.7% and 24.0% for the nanohole and the nanorod array, respectively, giving a larger difference between the two structures. This implies that light trapping in the small volume is more efficient for the nanohole array. Indeed, even when 750 nm<λ<1 μm where absorption in the thick structure (1.193 mm) is lower for the nanohole array, the thin nanohole array (2.33 μm) absorbs more strongly than the nanorod array.

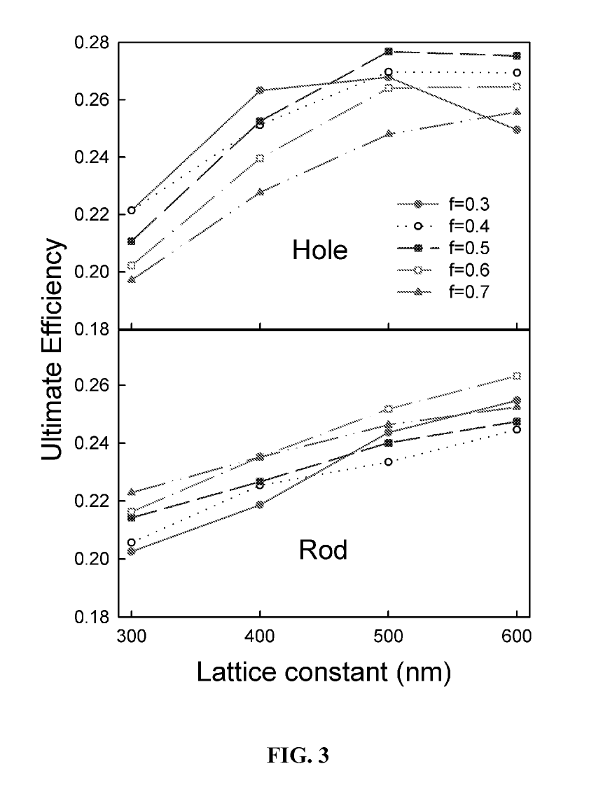

To determine whether nanohole arrays have a higher efficiency than nanorod arrays given other structural parameters, we calculate the efficiency for various lattice constants and filling fractions when d=2.33 μm as shown in FIG. 3. Nanohole arrays show a higher efficiency in most cases and the optimum efficiency found in the range of parameters investigated is also higher for nanohole arrays. The optimum efficiency is found to be 27.7% for nanohole arrays of the same structure as in FIG. 2 and 26.3% for nanorod arrays of a=600 nm and f=0.6. The optimum structural parameters for the nanorod array agree with theory but the efficiency might increase further by increasing the lattice constant. The general trend that the efficiency increases as the lattice constant becomes larger also agrees with theory where such an effect was attributed to the increasing number of waveguide modes. The coupling of light to the waveguide modes can also be considered.

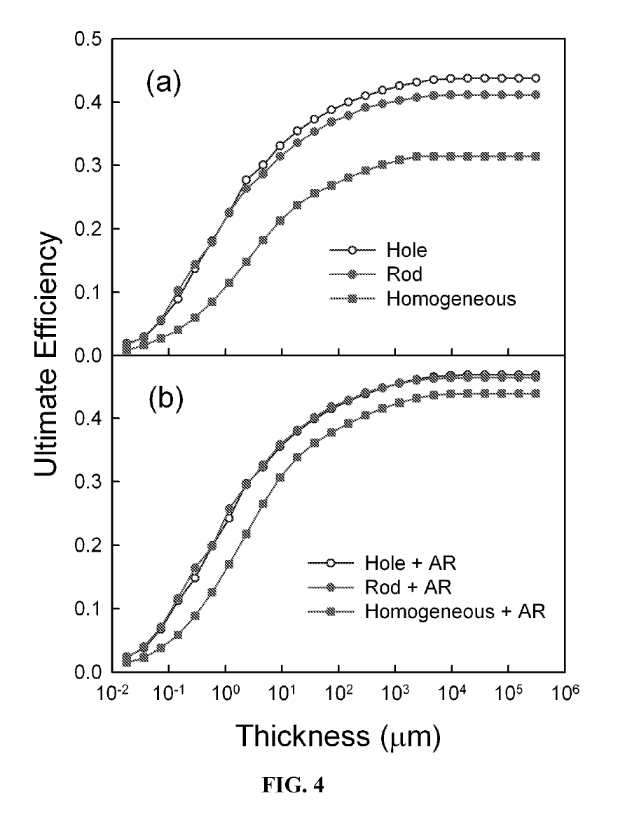

For the optimum lattice constant and filling fraction found for d=2.33 μm, we calculate the thickness dependence of the efficiency for both the nanohole and the nanorod array as shown in FIG. 4, plot (a). In both cases, the efficiency is higher than a homogeneous c-Si film, which has not been achieved for small lattice constants. The nanohole array shows higher efficiencies than the nanorod array for the practical cases where efficiencies above 25% are desired. The maximum efficiency of 31.4% for a homogeneous film is achieved for nanohole arrays with the thickness of only around 7 μm and for nanorod arrays of over 9 μm.

However, the efficiency of a homogeneous film can also be improved by an antireflection (AR) coating. For example, a silicon nitride (Si₃N₄) AR coating can improve the efficiency significantly. Using a standard dielectric function of Si₃N₄, the optimum thicknesses of the coatings are found to be 58 nm, 62 nm, and 62 nm for the nanohole array, the nanorod array, and the homogeneous film, respectively, when the c-Si layer thickness is 2.33 μm. The efficiency improves with these AR coatings in each case, as shown in FIG. 4, plot (b). The difference in efficiency between the nanohole and the nanorod array becomes very small with the AR coatings. Our results indicate that a nanohole array without an AR coating yields a higher efficiency than the AR coated homogeneous film except at very large thicknesses. For example, the efficiency for the 2.33 μm nanohole array can be achieved with the AR coated homogeneous c-Si thickness of 6 μm. This result is the consequence of the larger photonic density of states for the nanohole array shown in FIG. 1C.

Since the thickness of c-Si in commercial solar cells is around 300 μm, we can estimate, from FIG. 4, plot (b), the nanohole array thickness that is required to give the same ultimate efficiency as the c-Si thickness of commercial solar cells. A 300 μm thick homogeneous film with the AR coating specified earlier has an efficiency of 40.5%. The AR coated nanohole array of 50 μm thickness gives an identical efficiency. Therefore, the nanohole array requires one-sixth the thickness of a comparable crystalline wafer and, because the filling fraction is 0.5, twelve times less c-Si by mass. Note that this estimate is conservative because the nanohole array structure and its AR coating have not been optimized at this thickness. The maximum efficiency of 46.8% for the AR coated nanohole array is not far from the black body limit of 49.5% for a band gap of 1.1 eV. This result shows that our nanohole array couples well to incident sunlight.

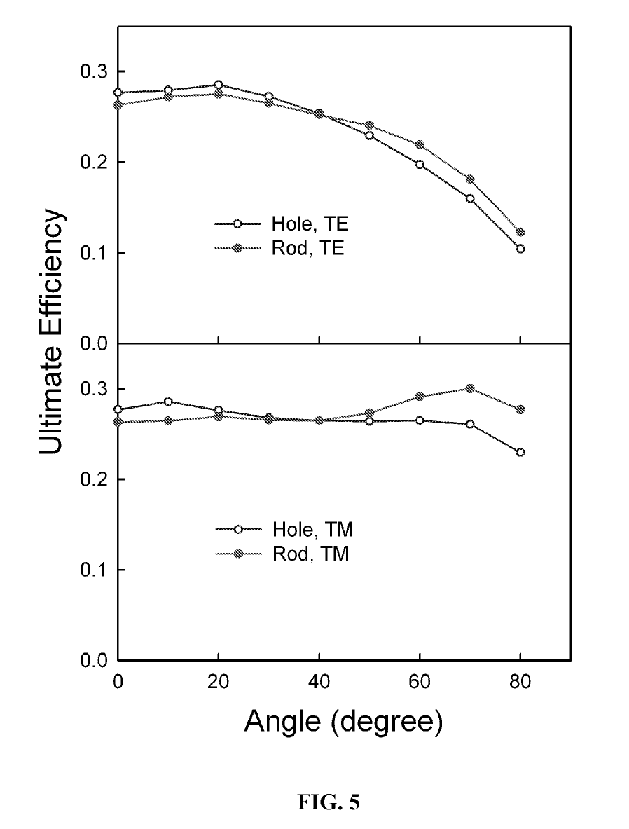

As the incidence angle of sunlight can deviate from the surface normal, we calculate the angular dependence of efficiency for the nanohole and nanorod structures. FIG. 5 suggests that, for both structures, the transverse-electric (TE) polarization has a stronger dependence on the angle of incidence than the transverse-magnetic (TM) polarization. The nanohole array is more absorptive than the nanorod array when the angle is less than 40 degrees. Larger angles are less important than smaller ones because the amount of light incident on a given area of solar cells decreases as the angle increases.

When utilized for semiconductor photovoltaic cells, the structures of the present invention can include p-n junctions (or p-i-n junctions as standard in various PV cells) and contacts. Regarding p-n junctions, at least two configurations can be contemplated. One is a regular layered p-n or p-i-n junction structure as found in some photovoltaic cells, which can be made of thin layers of p type, intrinsic, or n-type films deposited sequentially. In this case, the total thickness of all layers corresponds to the thickness of the entire structure discussed herein, and the holes are fabricated in such layered structures (e.g., the hole direction being perpendicular to the plane of the layers). Passivation of the side walls of the holes can be implemented, for example by oxidation, to decrease surface recombination. Another type of junction enabled by hole structures, is to have p-n or p-i-n layers in the plane of the film by doping laterally or depositing thin layers conformally along side walls. In any of these embodiments, electrical contacts can be made by any of several techniques as known in the art.

To summarize, the optical properties of c-Si nanohole array structures are demonstrated to be advantageous for solar photovoltaic applications and their light absorption properties are better than nanorod arrays. Calculations indicate that a nanohole array structure requiring one-twelfth the c-Si mass and one-sixth the thickness of a standard 300 μm Si wafer will have an equivalent ultimate efficiency. The strong optical absorption is attributed to both effective optical coupling between the array and the incident sunlight as well as the high density of waveguide modes.

Other embodiments of the invention include nanohole array structures where the holes only partially penetrate through a semiconductor lattice structure (i.e., the hole does not tunnel completely through the substrate). For instance, fabrication of such nanohole arrays may involve chemical etch processes, or other methods, to formulate a series of non-penetrating holes. By changing the etch depth, the light trapping performance of the nanohole structures can be altered and even improved. In some embodiments, non-penetrating nanohole array structures can exhibit enhanced photon capture efficiencies relative to nanohole array structures with penetrating holes.

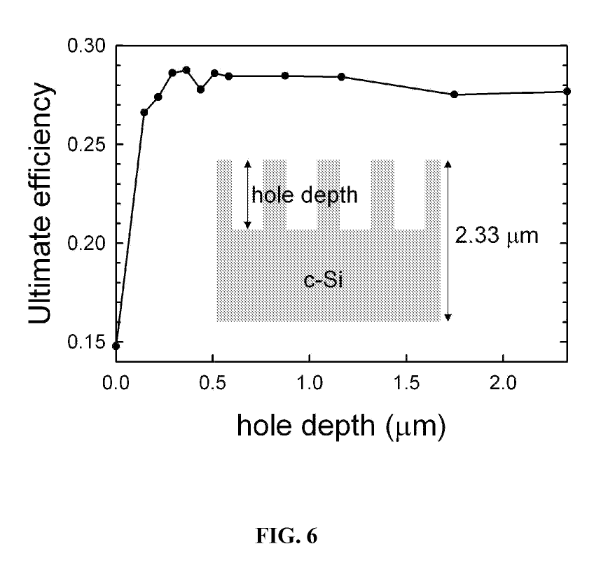

As an example, when nanoholes are formed having a depth in the submicron size range, the absorption in silicon can be even stronger than that of nanoholes drilled through the crystalline silicon (c-Si) substrate. The results of calculations made for non-penetrating nanoholes, consistent with the methodologies described herein, are depicted in FIG. 6, which shows the ultimate efficiency as a function of the depth of nanoholes on a c-Si film of thickness 2.33 μm. The efficiency appears to reach a maximum when the hole depth is roughly around 364 nm.

### Nanoprotrusions and Nanopits

Some embodiments of the present invention are directed to arrays of nanostructures distributed on a substrate that can act as radiation capture structures in devices such as solar photovoltaics. In some instances, these nanostructures can be embodied as one or more nanoprotrusions and/or nanopits that can extend from a surface of the substrate. A nanoprotrusion is a nanosized features that extends away from a surface of a substrate. A nanopit is a nanosized features that extends into a surface of a substrate.

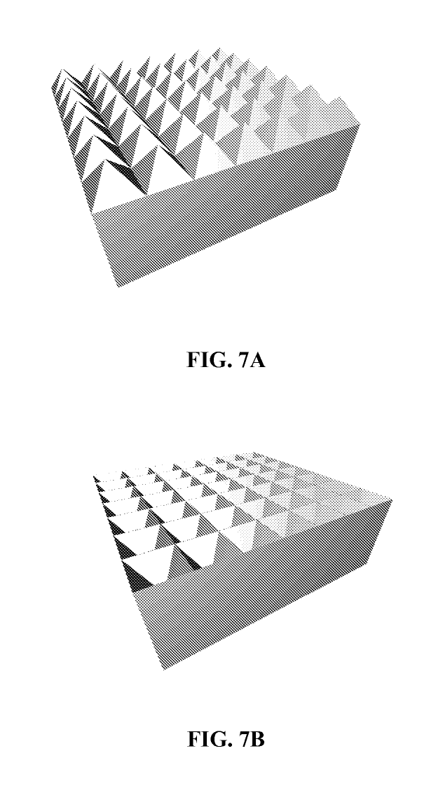

While any type of shape of structure(s) can be utilized for a nanostructure, in some embodiments the nanostructure is a nanopyramid as illustrated in FIG. 7A. Thus, when embodied as a nanoprotrusion, the pyramid has an apex that extends from the surface of the substrate (e.g., if the substrate is a bilayered p-n material conjugate, the apex of the pyramid can be farther from the p-n junction that the base). When embodied as a nanopit as shown in FIG. 7B, the pyramid has an apex that extends into the surface of the substrate (e.g., if the substrate is a bilayered p-n material conjugate, the apex of the pyramid can be closer to the p-n junction that the base). The pyramid can utilize a variety of geometries (e.g., different base to height ratios, base geometries such as square or triangular etc.). In some instances, the pyramid structure geometry is at least partially dictated by the etching of a set crystal structure of a crystalline substrate (e.g., a c-Si substrate). For example, for a c-Si (100) substrate surface, wet etching of the surface sites will fix the base to height ratio of etched inverted pyramid structures. It is understood that the term “nanopyramid” does not restrict the shape to a perfect geometrical pyramid. Indeed, during the fabrication of nanostructures by methods that can involve etching or imprinting materials such as polycrystalline silicon, it is understood that defects and/or blunting of edges, or an apex, can occur. These less than perfect geometrical nanopyramids can still be utilized with embodiments herein, and are within the scope of the present invention. In some embodiments, geometrically imperfect nanostructures can result in a device with a performance that is substantially similar, better, or somewhat degraded relative to a device using geometrically perfect nanostructures.

Since the nature of the substrate surface to be etched can dictate the geometry of nanostructures, in some embodiments a substrate comprises a lower grade silicon substrate that has a layer of higher quality silicon (e.g., a c-Si surface), which can be used in forming nanostructures such as nanoprotrusions and nanopits.

The distribution of the arrays of nanostructures can be varied. For example, chemical wet etching on a c-Si substrate of (100) orientation results in random pyramid structures of size range 2-10 μm. Before etching, a periodic structure can be defined on the surface using various lithographic techniques such as photolithography, electron beam lithography, nanosphere lithography etc. Predefinition of a square mesh, or other types of periodic distributions, and subsequent etching can produce a submicrometer array of inverted pyramids. With other etching techniques including reactive ion etching and plasma etching, other structures can also be created. For example, pyramid arrays and their variations can be fabricated.

Compared to nanohole arrays, inverted pyramids and pyramids can offer several advantages. First, the surface area of inverted pyramids and pyramids is much smaller, which will reduce the surface recombination of charge carriers significantly. The increase of surface area over a flat surface is only 1.73 times for inverted pyramids obtained by wet etching in comparison to around 12 times for optimized nanohole arrays of 2.33 mm thickness. Second, as the optical density changes gradually along the pyramid axis, incident light couples efficiently to the optical modes in inverted pyramids and pyramids.

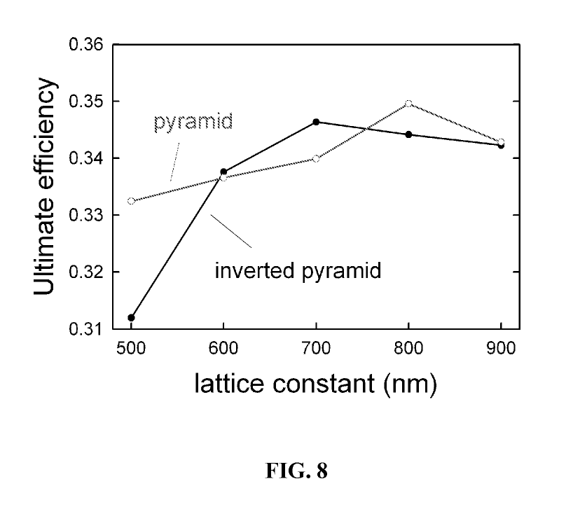

To document these potential advantages, the optical absorption of c-Si inverted pyramid and pyramid structures on a periodic array were calculated using the methods described herein. At the back of the c-Si substrate, a silver reflector was utilized to increase the optical path length. Other types of metallic or non-metallic materials can also be utilized as a reflector. FIG. 8 shows the variation of ultimate efficiency as the lattice constant changes according to the calculation. The performance between inverted pyramids, pyramids, and nanoholes can be compared. The optimum lattice constant for nanohole arrays was found to be 500 nm, yielding an efficiency of 27.7%. When a silver reflector is placed at the backside, the efficiency increases to 29.6%. At the same lattice constant, the efficiency of inverted pyramids is 31.2%, which is even higher. The optimum lattice constant occurs at 700 nm and the optimum efficiency is 34.6% which accounts for a 5% increase over nanohole arrays. Pyramid arrays show an even higher efficiency of 35.0% at a lattice constant of 800 nm.

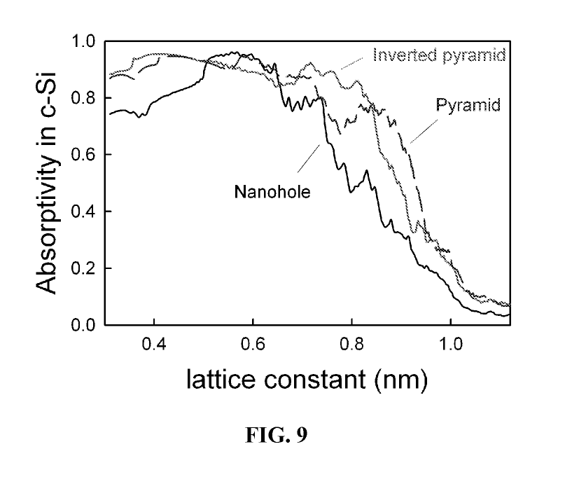

FIG. 9 compares the spectra of absorption in c-Si between inverted pyramids, pyramids and nanoholes for the optimum structural parameters as determined in the aforementioned calculations. Without being held to any particular theory, the improvement in absorption for pyramids and inverted pyramids over nanoholes below 0.5 μm is believed to result from better antireflection characteristics. Absorption in longer wavelengths is also stronger for pyramids and inverted pyramids, indicating more efficient light trapping. This remarkable increase in absorption suggests that pyramids and inverted pyramids have strong potential for their use in practical devices such as solar photovoltaics.

It should be noted that the enhanced efficiency of radiation capture structures using nanostructures is not apparent in light of the results with respect to larger structures such as similar geometrical micron-sized structures utilized on similar substrates. Indeed, the physics of the photon-directing processes are completely different, with nanostructured features relying on optical diffraction while macroscopic sized features rely on classical reflection and refraction. Accordingly, a skilled artisan cannot a priori predict the performance of devices with nanostructures in light of knowledge of devices with micron-sized features.

Inverted pyramids can be prepared using simple wet etching processes as disclosed in B. Päivänranta, T. Saastamoinen, and M Kuittinen, “A Wide-Angle Antireflection Surface for the Visible Spectrum”, Nanotechnology 20, 375301 (2009). Y. C. Chang, G. H. Mei, T. W. Chang, T. J. Wang, D. Z. Lin, and C. K. Lee, “Design and Fabrication of a Nanostructured Surface Combining Antireflective and Enhanced-Hydrophobic Effects”, Nanotechnology 18, 285303 (2007), all of which are incorporated herein by reference in their entireties. Using inverted pyramids as a mold, pyramid structures can also be created. In both cases, some variations in structures will also provide good optical absorption. For example, etching processes including reactive ion etching and plasma etching can result in such variations. In some embodiments, the silicon layer is not limited to a high quality crystal but can include polycrystalline silicon. In general, the results shown here for silicon can also be extended to other materials as substrates for radiation capture structures such as solar photovoltaics. When silicon is used, the film thickness can be in a range of about 0.1 to about 50 micrometers and/or about 0.5 to about 10 micrometers, although it will be appreciated that any suitable thickness can be used.

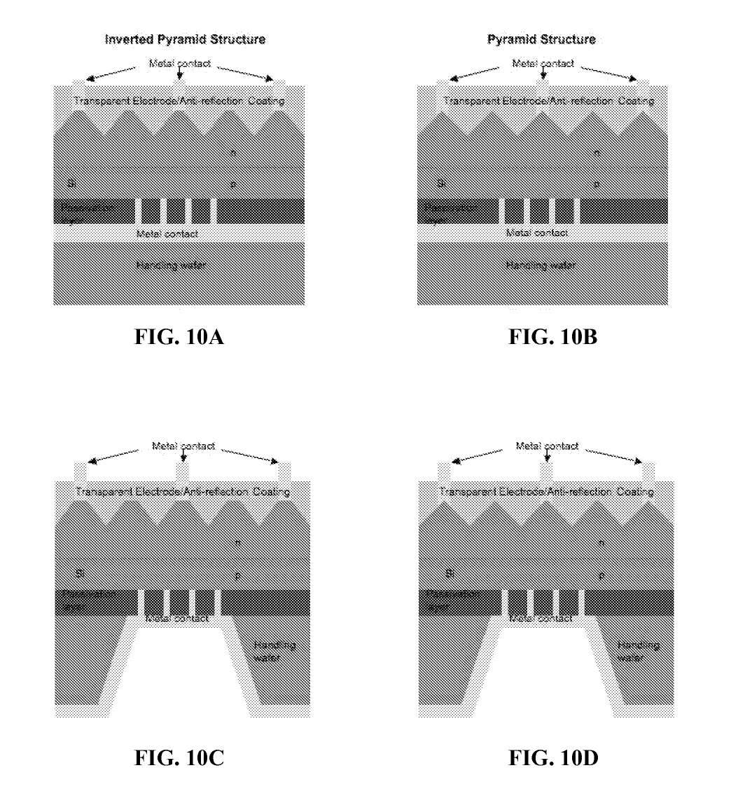

FIGS. 10A-10D illustrate some embodiments of photovoltaic devices that can utilize radiation capture structures consistent with those described in the present application. While these nanostructures are nanopyramids, it is understood that other shapes can also be utilized. In these embodiments, the basic structure of the device consists of the thin photovoltaic silicon n-/i-/p-layer (or simply p-n layer) with the top of the device patterned with the pyramid/inverted pyramid structure, top transparent electrode and/or antireflection coating, bottom passivation layer, and top and bottom metal contacts.

The photovoltaic device layer can be made from crystalline, polycrystalline or amorphous silicon and its optimum thickness will depend on the type of silicon that will be used. The silicon devices (e.g., substrate) can be created from bulk silicon wafers, Silicon-On-Insulator (SOI) wafers, ultrathin silicon wafers deposited on handling substrates by various ingot growth techniques, thermal vapor, physical vapor, chemical vapor, electrochemical, or a combination of these deposition techniques. The n- and p-type doping can be done during the growth/deposition or incorporated at a later stage by standard techniques such as Spin On Dopants (SOD), thermal diffusion, implantation etc.

To produce the periodic pyramid/inverted pyramid structures, among other types of nanostructures, a combination of mask and etching techniques as well as deposition in molds can be employed. Lithographic techniques such as photo, electron beam, imprint, nanosphere lithography etc can be used to produce the periodic mask and then the etching can be completed using wet and/or physical etching techniques such as chemical, electrochemical, photoelectrochemical, catalytic assisted etching, oxidation, Reactive Ion Etching (RLE), ion sputtering etc. Organic/plastic/semiconducting/metallic molds with the periodic pyramid/inverted pyramid structure can also be used in conjunction with the silicon deposition techniques to produce the desired structure. The top anti-reflection and/or transparent electrode as well as the bottom passivation layer can be deposited through oxidation, physical vapor, chemical vapor, electrochemical, or a combination of these deposition techniques.

Similar mask and etching techniques as stated previously can be used to etch through the passivation, transparent electrode and/or antireflection coating, to expose the silicon layer. Subsequently metal can be deposited by thermal vapor, physical vapor, chemical vapor, electrochemical, or a combination of these deposition techniques to collect the carriers from the silicon device layer. Additional dopant diffusion may be used at the metal contact sites to make ohmic contact and not degrade the overall device efficiency. Novel nanostructured films such as polymer films embedded with metal nanowires, nanoparticles, nanotubes, etc. can be used to substitute any one of the top and bottom passivation layers, antireflection layers, and/or metal layers. A handling wafer can be used to support the complete photovoltaic structure. This handling wafer can be on top or bottom of the device structure and made out of either metal, plastic, polymer, semiconductor, and insulator as long as it is designed appropriately to allow for the adequate transmission of the photons and collection of the carriers from both sides.

FIGS. 10A and 10C illustrate potential photovoltaic devices with inverted pyramid nanostructures and FIGS. 10B and D illustrate potential photovoltaic devices with pyramid nanostructures. The back contact for the devices shown in FIGS. 10C and 10D is done through the handling wafer.

While some embodiments of photovoltaic devices utilize one or more features described herein with respect to FIGS. 10A-10D, it is understood that many other configurations can also be utilized to form such devices. For instance, in some embodiments, a layer of p-type material can have a surface including the plurality of nanostructures (e.g., nanopits or nanoprotrusions). A conformal layer of n-type material can be fabricated on the surface of the p-type material. Of course, variations of these embodiments, such as use of a n-type layer having the nanostructures with a p-type conformal layer, are also within the scope of the present invention, among other configurations including those known to one skilled in the art.

As well, further modifications of the photovoltaic devices described herein can be made to improve such characteristics as costs and manufacturing ease. For instance, relative to FIGS. 10A-10D, n-type and p-type layers can be deposited on a thicker silicon layer that is of a different quality relative to the n-type and p-type layers, or can be a substrate such as glass. Accordingly, embodiments of a photovoltaic cell consistent with the scope of the present invention can be any that utilizes any combination of the patentable features in the present disclosure and which include other structural features, including those known to one skilled in the art.

Other embodiments of the present invention are directed to techniques to improve the efficiency of the radiation capture structures described herein. For instance, in some embodiments arrays of nanostructures are oriented in a skewed manner, which can act to enhance photon capture and/or charge separation relative to a plurality of non-skewed nanostructures that are similarly sized and fabricated on a substrate. In some embodiments, the improvement in light trapping can be comparable to the statistical ray optics limit. Some skewed nanostructures refer to nanostructures which exhibit a mirror symmetry in at least one orientation on a substrate when arranged in a certain lattice, but can be arranged in a different lattice on a substrate such that the mirror symmetry is broken.

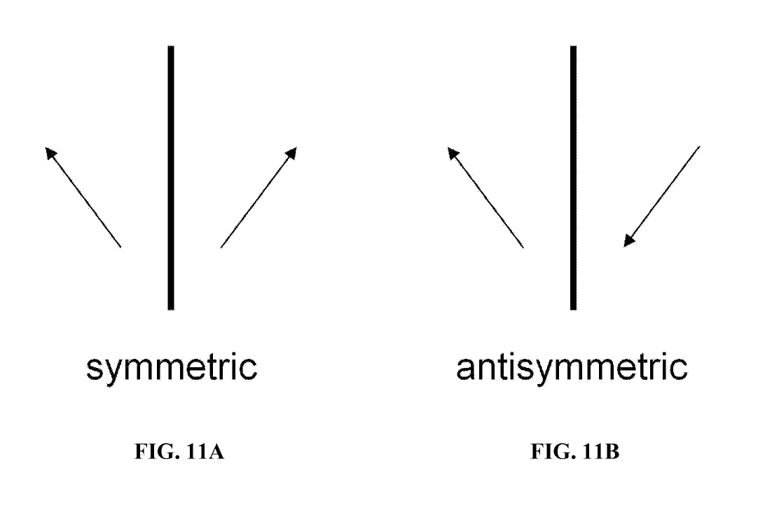

The increase in the coupling of incident light to the eigenmodes inside a diffracting periodic structure by breaking mirror symmetry was pointed out in O. Kilic et al., Controlling Uncoupled Resonances in Photonic Crystals Through Breaking the Mirror Symmetry, Opt. Express 16, 13090-13103 (2008). When the periodic structure has a mirror symmetry plane, the electric fields of the eigenmodes that have a wave vector parallel to the mirror plane can be either symmetric or antisymmetric about the plane as schematically shown in FIGS. 11A and 11B. Because incident plane waves are antisymmetric about the mirror plane perpendicular to the electric field direction, the modes that are symmetric about the mirror plane do not couple to the incident light. Accordingly, absorption will not be very efficient for structures that have mirror symmetries. Thus, the strategy to increase absorption is to break the mirror symmetries of the structure.

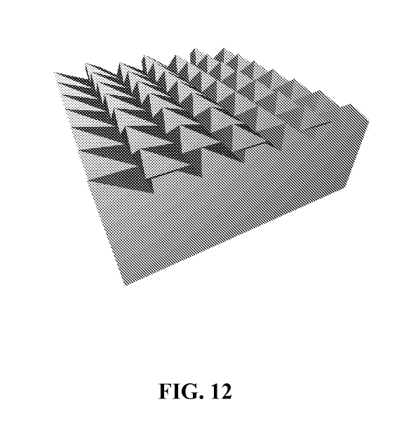

Some embodiments of the present invention that can be implemented are demonstrated using the illustration of a triangular array of skewed pyramids shown in FIG. 12. It is understood that other skewed nanostructures can also be utilized with these embodiments as described herein (e.g., using different array arrangements of the structures such as square or random and/or orienting the nanostructures in various manners). The symmetry breaking in this case is achieved by (1) tilting the pyramids and (2) arranging the skewed pyramids in triangular lattice. In this way, mirror symmetry is broken in all directions. Similar techniques have been used in optimizing pyramid structures that are much larger than the light wavelength. M. A. Green and S. R. Wenham, Optical properties of solar cells using tilted geometrical features, U.S. Pat. No. 5,080,725 (1992). P. Campbell, S. R. Wenham, and M. A. Green, Light Trapping and Reflection Control in Solar Cells Using Tilted Crystallographic Surface Textures, Sol. Energy Mater. Solar Cells 31, 133-153 (1993). In these methods, the advantage of tilted pyramids was discovered by geometric optics simulations, though the optimized structure had a mirror symmetry plane. In some embodiments such as those depicted in FIG. 12, the pyramids of nanoscale sizes that support optical diffraction and are arranged such that mirror symmetry is totally broken.

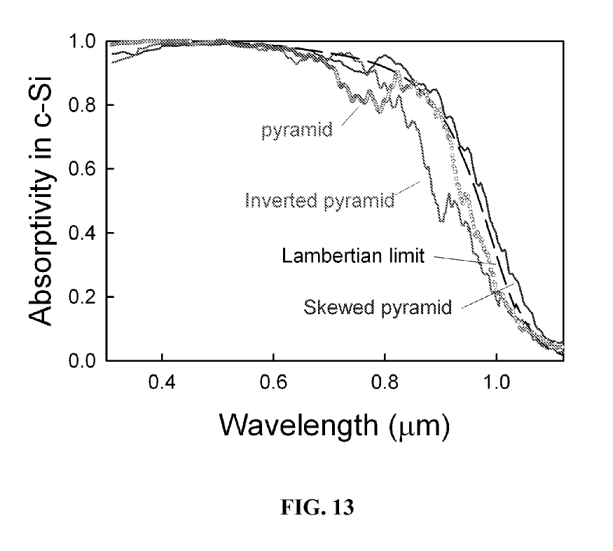

FIG. 13 shows the results of calculations, made consistent with the methods described above, for skewed pyramids with 900 nm period formed by etching the front surface of 2.33 μm thick Si film. A 90 nm antireflection layer with refractive index 2.08 is conformally coated on the structure. At the backside of the film, a flat Ag reflector is used with a SiO₂ layer of 717 nm thickness in between. Compared to pyramids and inverted pyramids with the same antireflection coating and SiO₂ layer, the skewed pyramids show significant improvements. The ultimate efficiency of the skewed pyramids is 40.2%. This value is higher than the ultimate efficiency limit (39.7%) of Lambertian light trapping for the same Si mass. E. Yablonovitch and G. D. Cody, Intensity Enhancement in Textured Optical Sheets for Solar Cells, IEEE Trans. Electron Devices 29, 300-305 (1982). Note that this limit refers to isotropic incidence of light. Accordingly, the skewed pyramids calculation cannot exceed this limit if averaged over the whole solid angles. However, because the skewed pyramids spectrum was obtained for normal incidence, this limit is broken. Still, this result is remarkable considering the significant amount of light lost in the Ag in the calculated instance, whereas the Lambertian limit assumes no loss.

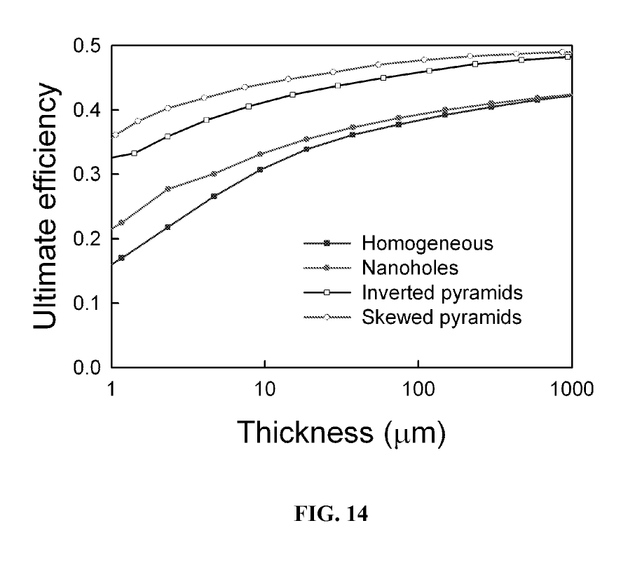

A comparison of the performance of some of the nanostructures described herein is shown in FIG. 14, which presents plots of the thickness dependence of the ultimate efficiency for various nanostructures. Each structure is optimized for the thickness of 2.33 μm and has an antireflection coating on it. It can be seen that, over all thicknesses investigated, the efficiency increases in the order of homogeneous film, nanoholes, inverted pyramids, and skewed pyramids. To obtain an efficiency of a homogeneous film of thickness 300 μm, less than 3 μm is needed if skewed pyramids are used according to FIG. 14.

Skewed pyramids show a high efficiency and can be fabricated in a number of manners. Lithography techniques and reactive ion etching in off-normal directions might be utilized. B. Päivänranta, T. Saastamoinen, and M Kuittinen, A wide-angle antireflection surface for the visible spectrum, Nanotechnology 20, 375301 (2009). M. Nakada, K. Takahashi, T. Takahashi, A. Higo, H. Fujita, and H. Toshiyoshi, “Development of Skewed DRIE Process and its Application to Electrostatic Tilt Mirror”, IEEE 22^{nd} International Conference on MEMS, 1087 (2009).

In summary, the light trapping properties of the arrays of nanorods, nanoholes, pyramids, inverted pyramids, and skewed pyramids are documented. Nanoholes exhibit better optical absorption than nanorods indicating strong potential to be used for solar photovoltaics. Pyramids and inverted pyramids show even stronger light trapping properties. Between these two, inverted pyramids are preferred in terms of fabrication. Skewed pyramids are extremely powerful absorbers and can be comparable to ideal Lambertian light trapping structures.

All papers, patents, patent applications and other publications cited herein are expressly incorporated by reference in their entireties.

What is claimed is:

1. A photovoltaic structure, comprising:
a semiconductor lattice structure of a first dopant type exhibiting a plurality of nanoholes,
a semiconductor lining of a second dopant type disposed at least partially within the nanoholes to provide a conformal inner coating, thereby presenting a p-n junction, whereby said nanoholes are sized to substantially trap incident light and facilitate carrier separation.

2. The photovoltaic structure of claim 1, wherein the photovoltaic structure is characterized by a lattice constant in a range from about 100 nm to about 1 micrometer.

3. The photovoltaic structure of claim 1, wherein the plurality of nanoholes are characterized by a depth of less than about 200 μm.

4. The photovoltaic structure of claim 3, wherein the depth of the plurality of nanoholes is greater than about 100 nm.

5. The photovoltaic structure of claim 1, wherein the photovoltaic structure is characterized by a fill fraction in a range from about 0.25 to about 0.75.

6. The structure of claim 1 wherein the p-n junction is a homojunction.

7. The structure of claim 1 wherein the p-n junction is a hereterojunction.

8. The structure of claim 1, wherein at least one of the plurality of nanoholes penetrates only partially through the semiconductor lattice structure.

9. The structure of claim 8, wherein the at least one of the plurality of nanoholes exhibits a depth less than about 2 μm.

10. A radiation absorbing structure comprising:
a semiconductor lattice comprising at least a first and a second layer of semiconductor material, the second semiconductor material of a different dopant composition relative to the first semiconductor material; and
the lattice being porous and having a plurality of light trapping holes.

11. The radiation absorbing structure of claim 10 wherein the structure has a lattice constant in a range from about 300 nm to about 700 nm.

12. A nanoscale radiation capture structure, comprising:
a first doped layer and a second doped layer, the first doped layer characterized by a plurality of nanostructures on a surface of the first doped layer, the nanostructures comprising at least one of a nanoprotrusion and a nanopit, each nanostructure extending a selected distance from the surface of first doped layer, the plurality of nanostructures configured to enhance at least one of photon capture and charge separation properties of the radiation capture structure when radiation contacts the surface of the first doped layer.

13. The structure of claim 12, wherein the first and second layer form a p-n junction.

14. The radiation capture structure of claim 12, wherein the plurality of nanostructures comprise tapered nanostructures.

15. The radiation capture structure of claim 12, wherein the plurality of nanostructures comprises a plurality of nanopits.

16. The radiation capture structure of claim 15, wherein the nanopits protrude at least partially into the second doped layer.

17. The radiation capture structure of claim 15, wherein the nanopits penetrate only partially into the first doped layer.

18. The radiation capture structure of claim 12, wherein the plurality of nanostructures are periodically fabricated on the surface of the first doped layer.

19. The radiation capture structure of claim 12, wherein the radiation capture structure comprises a c-Si material.

20. The radiation capture structure of claim 19, wherein the c-Si material comprises one of a single crystal of silicon, microcrystalline silicon, and multicrystalline silicon.

21. The radiation capture structure of claim 15, wherein the nanopits comprise nanoholes penetrating only partially into the first doped layer.

22. The radiation capture structure of claim 21, wherein the selected distance is less than about 2 microns.

23. The radiation capture structure of claim 12, wherein the plurality of nanostructures comprises a plurality of pyramid structures.

24. The radiation capture structure of claim 23, wherein each pyramid structure comprises an apex and a base, wherein the apex is closer to the p-n junction than the base.

25. The radiation capture structure of claim 23, wherein each pyramid structure comprises an apex and a base, wherein the base is closer to the p-n junction than the apex.

26. The radiation capture structure of claim 23, wherein the plurality of pyramid structures exhibit a lattice constant in a range from about 400 nm to about 1200 nm.

27. The radiation capture structure of claim 23, wherein the first doped layer comprises a crystalline substrate with a (100) orientation.

28. The radiation capture structure of claim 12, wherein the plurality of nanostructures comprises a plurality of skewed nanostructures that act to enhance at least one of photon capture and charge separation relative to a plurality of non-skewed nano structures.

29. The radiation capture structure of claim 28, wherein the nanostructures exhibit broken mirror symmetry.

30. The radiation capture structure of claim 28, wherein the plurality of skewed nanostructures are fabricated in a triangular lattice arrangement on the surface of the first doped layer.

31. The radiation capture structure of claim 28, wherein the plurality of skewed nanostructures are fabricated in a square lattice arrangement on the surface of the first doped layer.

32. The radiation capture structure of claim 12, wherein the first doped layer comprises silicon.

33. The radiation capture structure of claim 12, wherein the radiation capture structure is at least a portion of photovoltaic structure.

34. The radiation capture structure of claim 33, further comprising:
a reflector layer coupled with the first and second doped layers and configured to increase the optical path length of photons captured by the radiation capture structure.

35. The radiation capture structure of claim 33, wherein the photovoltaic structure further comprises at least one of a transparent electrode and an anti reflection coating coupled to the surface of the first doped layer.

36. The radiation capture structure of claim 33, wherein the photovoltaic structure further comprises a first electrical contact coupled to the first doped layer and a second electrical contact coupled to the second doped layer.
